(19) United States
(12) Patent Application Publication
(10) Pub. No.: US 2009/0078944 A1
(43) Pub. Date: Mar. 26, 2009

(54) Light emitting device and method of manufacturing the same

(75) Inventors: Masashi Kubota, Kyoto (JP); Kuniyoshi Okamoto, Kyoto (JP)

Correspondence Address: RABIN & Berdo, PC, 1101 14TH STREET, NW, SUITE 500, WASHINGTON, DC, 20005, US

(73) Assignee: ROHM CO., LTD., Kyoto (JP)

(21) Appl. No.: 12/230,883

(22) Filed: Sep. 5, 2008

(30) Foreign Application Priority Data
Sep. 7, 2007 (JP) 2007-233015

(51) Int. Cl. H01L 33/00

(52) U.S. Cl. 257/88; 438/29; 257/E33.067

(57) ABSTRACT

This semiconductor light emitting device includes an optical cavity made of a group III nitride semiconductor having a major growth surface defined by a nonpolar plane and including a pair of cavity end faces parallel to c-planes, and a reflecting portion made of a group III nitride semiconductor having a major growth surface defined by a nonpolar plane and having a reflective facet opposed to one of the pair of cavity end faces and inclined with respect to a normal of the major growth surface. The optical cavity and the reflecting portion may be crystal-grown from the major surface of the substrate. The substrate is preferably a group III nitride semiconductor substrate having a major surface defined by a nonpolar plane.

### BACKGROUND OF THE INVENTION

1. Field of the Invention

The present invention relates to a semiconductor light emitting device employing group III nitride semiconductors and a method of manufacturing the same. Group III nitride semiconductors are group III-V semiconductors employing nitrogen as a group V element, and typical examples thereof include aluminum nitride (AlN), gallium nitride (GaN) and indium nitride (InN), which can be generally expressed as AlₓIn_{y}Ga_{1-x-y}N (0≦x≦1, 0≦y≦1 and 0≦x+y≦1).

2. Description of Related Art

A semiconductor laser perpendicularly emitting light from a major surface of a semiconductor substrate is referred to as a surface emitting laser. In a general surface emitting laser, a cavity is formed by arranging reflecting mirrors on upper part and lower part of a semiconductor thin film, with a cavity direction parallel to a normal direction of the major surface of the semiconductor substrate.

In the surface emitting laser having this structure, however, the cavity length is small and hard to control, and light amplification is insufficient.

On the other hand, “An InGaN-based horizontal-cavity surface-emitting laser diode” by Tetsuya Akasaka et al., Applied Physics Letters, Vol. 84, No. 20, American Institute of Physics, pp. 4104-4106 discloses a laser diode including a cavity parallel to a major surface of a substrate and a reflecting mirror reflecting a laser beam emitted from the cavity in a direction diverging from the major surface of the substrate. According to this structure, the cavity length can be so easily controlled as to solve the aforementioned problems in the surface emitting laser.

A method of manufacturing the laser diode disclosed in this document includes the steps of: forming a laser diode structure consisting of group III nitride semiconductor layers on an SiC substrate having a major surface defined by a c-plane; forming a trench to surround a portion for forming the cavity by dry etching; and selectively regrowing GaN layers doped with Mg on wall surfaces of the trench. A surface of the GaN layer grown on an inner sidewall of the trench is defined by a (11-20) plane perpendicular to the major surface of the substrate, while a surface of the GaN layer grown on an outer sidewall of the trench is defined by a (11-22) plane inclined by 58° with respect to the major surface of the substrate. Thus, a horizontal cavity having a pair of cavity end faces defined by (11-20) planes is formed on an inner side of the trench, while a reflecting surface consisting of a (11-22) plane opposed to the cavity end faces is formed on an outer side of the trench.

In the structure according to the aforementioned document, however, the trench must be formed by dry etching, and the GaN layers doped with Mg must be selectively regrown on the sidewalls of the trench, as hereinabove described. Therefore, the manufacturing steps are complicated. Further, the GaN layers formed in the vicinity of the cavity end faces are regions having neither laser structures nor light amplification function, and hence no gain corresponding to the cavity length is attained. If the cavity length is increased in order to compensate for this, the area occupied by a laser unit is increased. Therefore, if a large number of laser units are integrally arranged on the substrate, for example, the integration density on the surface of the substrate is reduced.

### SUMMARY OF THE INVENTION

An object of the present invention is to provide a semiconductor light emitting device that can be manufactured through simple steps and capable of improving a gain, and a method of manufacturing the same.

The foregoing and other objects, features and effects of the present invention will become more apparent from the following detailed description of the embodiments with reference to the attached drawings.

### BRIEF DESCRIPTION OF THE DRAWINGS

FIG. 1 is a schematic enlarged plan view for illustrating the structure of a semiconductor light emitting device according to an embodiment of the present invention.

FIG. 2 is a schematic sectional view for illustrating the structure of a laser unit in detail.

FIG. 3 is a schematic perspective view for illustrating a structural example of a cavity in detail.

FIGS. 4A to 4G are schematic sectional views schematically showing the steps of manufacturing the semiconductor light emitting device.

FIG. 5 is a schematic plan view for illustrating a pattern of an etching mask for partitioning group III nitride semiconductor crystals.

FIG. 6 is a sectional electron micrograph showing a result of an experiment of forming a zonal mask made of SiO₂ on a monocrystalline GaN substrate having a major surface defined by an m-plane and growing GaN crystals on both sides of the zonal mask.

### DETAILED DESCRIPTION OF PREFERRED EMBODIMENTS

A semiconductor light emitting device according to an embodiment of the present invention includes an optical cavity (the so-called horizontal cavity having a cavity direction parallel to a major growth surface) made of a group III nitride semiconductor having a major growth surface defined by a nonpolar plane and including a pair of cavity end faces parallel to c-planes, and a reflecting portion made of a group III nitride semiconductor having a major growth surface defined by a nonpolar plane and having a reflective facet opposed to one of the pair of cavity end faces and inclined with respect to the normal of the major growth surface.

According to this structure, the optical cavity emits light in a direction parallel to the major growth surface of the group III nitride semiconductor, and the light is applied to the reflective facet. The reflective facet is inclined with respect to the normal of the major growth surface, whereby the light reflected by the reflecting portion is guided to a direction intersecting with the major growth surface.

Both of the optical cavity and the reflecting portion are made of the group III nitride semiconductors having the major growth surfaces defined by the nonpolar planes (a- or m-planes). Therefore, both of the pair of cavity end faces of the optical cavity can be parallelized with the c-planes. The reflective facet of the reflecting portion is formed by an inclined surface opposed to one of the cavity end faces.

The group III nitride semiconductors having the major growth surfaces defined by the nonpolar planes can be crystal-grown by selective growth with a mask of a zonal pattern perpendicular to a c-axis, for example. At this time, a c-plane (−c-plane) appears on the +c-axis side of the mask, while a facet inclined with respect to both of the major growth surface and the normal thereof appears on the −c-axis side of the mask. In the semiconductor light emitting device according to the present invention, therefore, a facet forming one of the cavity end faces and the reflective facet can be simultaneously formed by simply crystal-growing the group III nitride semiconductors, without carrying out an additional regrowth step. In other words, no crystal regrowth on wall surfaces of a trench may be performed, dissimilarly to the aforementioned prior art. Therefore, the manufacturing steps are simplified.

The cavity end faces can be obtained by simply growing the group III nitride semiconductor forming the optical cavity, whereby the optical cavity can contribute to light amplification up to the portions of the cavity end faces. In the aforementioned prior art, the portions regrown on the wall surfaces of the trench have no laser structures, and hence no light amplification effect is attained on these portions. According to the structure of the present invention, on the other hand, the cavity end face opposed to the reflective facet is formed by crystal growth, whereby a laser structure can be provided up to the end face portions of the optical cavity. Therefore, a gain is obtained along the overall cavity length, whereby a semiconductor light emitting device improved in gain can be implemented.

The semiconductor light emitting device may further include a substrate, and the optical cavity and the reflecting portion may be made of group III nitride semiconductors crystal-grown from the major surface of the substrate. According to this structure, the optical cavity and the reflecting portion can be simultaneously prepared by forming the aforementioned mask on the substrate and selectively growing the group III nitride semiconductors having the major growth surfaces of the nonpolar planes.

Preferably, the substrate is a group III nitride semiconductor substrate having a major surface defined by a nonpolar plane. According to this structure, the optical cavity and the reflecting portion having excellent crystal structures can be formed by forming the aforementioned mask on the group III nitride semiconductor substrate having the major surface defined by the nonpolar plane and selectively growing the group III nitride semiconductors. Thus, a semiconductor light emitting device having excellent characteristics can be obtained.

A GaN substrate having a major surface defined by a nonpolar plane, for example, can be employed as the group III nitride semiconductor substrate. Particularly when a GaN monocrystalline substrate having a major surface defined by a nonpolar plane is employed, group III nitride semiconductors having excellent crystallinity with extremely small numbers of defects can be grown on the major surface thereof. Thus, the characteristics of the semiconductor light emitting device can be further improved.

Preferably, the optical cavity and the reflecting portion are formed by selective epitaxy growth on the major surface of the substrate. According to this structure, the optical cavity and the reflecting portion can be simultaneously formed by selective epitaxy growth, whereby the manufacturing steps are simplified.

Preferably, the semiconductor light emitting device further includes a reflecting film formed on the reflective facet. According to this structure, reflectivity in the reflecting portion can be improved, thereby improving light extraction efficiency. While the reflective facet may be employed as a reflecting surface reflecting the light from the cavity, the light extraction efficiency can be improved by improving the reflectivity with the reflecting film.

A DBR (Distributed Bragg Reflector), for example, may be employed as the reflecting film.

A plurality of light emitting units including pairs of the optical cavities and the reflecting portions may be arrayed on a substrate. According to this structure, the plurality of light emitting units are arrayed on the substrate, thereby enabling general surface emission, for example.

A method of manufacturing a semiconductor light emitting device according to the embodiment of the present invention is a method of manufacturing a semiconductor laser device including an optical cavity and reflecting portion formed on a substrate, the optical cavity having a cavity direction parallel to a major surface of a substrate, the reflecting portion being arranged to reflect a laser beam generated by the optical cavity in a direction unparallel to the major surface of the substrate (more specifically, a direction for separating from the major surface of the substrate). This method includes a mask forming step of forming a mask of a prescribed pattern having openings corresponding to regions for forming the optical cavity and the reflecting portion on the substrate, and a crystal growth step of simultaneously forming a first group III nitride semiconductor crystal having a facet parallel to a c-plane defining a first cavity end face of the optical cavity and a second group III nitride semiconductor crystal for the reflecting portion having a reflective facet opposed to the first cavity end face and inclined with respect to the normal of the major surface of the substrate by growing a group III nitride semiconductor having a major surface defined by a nonpolar plane by selective epitaxy growth from the major surface of the substrate exposed from the openings of the mask.

According to this method, the optical cavity and the reflecting portion can be simultaneously formed by selective epitaxy growth from the openings of the mask, and the first cavity end face and the reflective facet opposed thereto can be simultaneously formed without requiring subsequent regrowth.

The method of manufacturing a semiconductor light emitting device may further include a step of forming a second cavity end face of the optical cavity by partitioning the first group III nitride semiconductor crystal on a position separating from the first cavity end face of the optical cavity by a prescribed cavity length. Thus, the second cavity end facet opposite to the reflective facet can be formed. The first group III nitride semiconductor crystal may be partitioned by etching (dry etching, for example), or by cleavage of the crystal.

The mask forming step may include a step of forming a plurality of linear masks on the major surface of the substrate in a striped manner. In this case, the crystal growth step preferably includes a step of growing an inter-mask group III nitride semiconductor crystal having a facet parallel to a c-plane on the side of a first linear mask and having another facet inclined with respect to the normal of the major surface of the substrate on the side of a second linear mask between each pair of linear masks adjacent to each other thereby opposing the facet forming the first cavity end face of the optical cavity and the reflective facet of the reflecting portion to each other through each linear mask. Preferably, the method of manufacturing a semiconductor light emitting device further includes a step of forming a second cavity end face of the optical cavity by partitioning the inter-mask group III nitride semiconductor crystal between each pair of linear masks adjacent to each other on a position separating from the first cavity end face by the prescribed cavity length.

According to this method, the inter-mask group III nitride semiconductor crystal integrating a portion (first group III nitride semiconductor crystal) for forming the optical cavity of a certain light emitting unit and a portion (second group III nitride semiconductor crystal) for forming the reflecting portion of another light emitting unit is grown between each pair of linear masks. The inter-mask group III nitride semiconductor crystal is partitioned to be divided into the two portions, while forming the cavity end faces of the optical cavity.

The inter-mask group III nitride semiconductor crystal may be partitioned by cleavage, or by etching (dry etching, for example). When the plurality of light emitting units consisting of the cavities and the reflecting portions corresponding thereto are arrayed on the substrate along a direction intersecting with the linear masks, the inter-mask group III nitride semiconductor crystal is preferably partitioned by etching (particularly by dry etching).

The method of manufacturing a semiconductor light emitting device may further include a step of partitioning the inter-mask group III semiconductor crystal at an interval along the linear masks. Thus, the plurality of light emitting units can be obtained by partitioning the inter-mask group III nitride semiconductor crystal at an interval in a direction along the linear masks.

The inter-mask group III nitride semiconductor crystal may be partitioned by cleavage, or by etching (dry etching, for example). When the plurality of light emitting units are arrayed on the substrate along the direction along the linear masks, the inter-mask group III nitride semiconductor crystal is preferably partitioned by etching.

The method of manufacturing a semiconductor light emitting device may further include a step of forming a reflecting film on the facet of the reflecting portion. Thus, the reflectivity of the reflecting portion can be increased, thereby improving the light extraction efficiency.

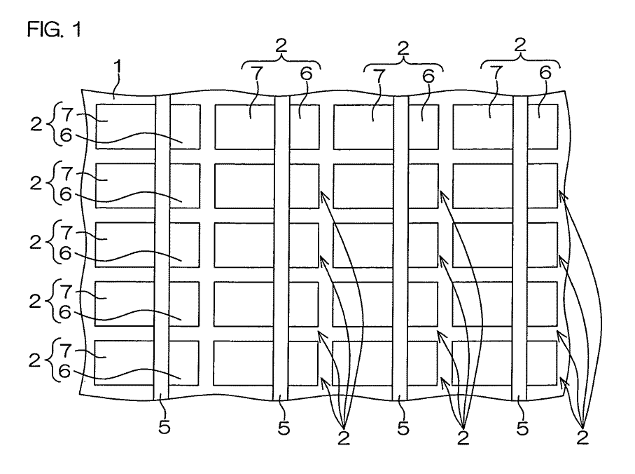

FIG. 1 is a schematic enlarged plan view for more specifically illustrating the structure of the semiconductor light emitting device according to the embodiment of the present invention. The semiconductor light emitting device is formed by arraying a plurality of laser units 2 (light emitting units) on a substrate 1. In other words, the plurality of laser units 2 are arranged along a row direction X and a column direction Y orthogonal to each other. Each laser unit 2 emits a laser beam 3 toward a direction intersecting with a major surface of the substrate 1. Thus, a laser source virtually capable of surface emission is constituted.

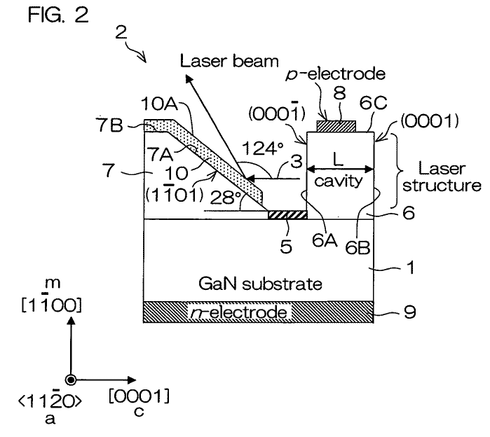

FIG. 2 is a schematic sectional view for illustrating the structure of each laser unit 2 in detail. In this example, the substrate 1 is a conductive substrate. More specifically, the substrate 1 is formed by a GaN substrate (more preferably a monocrystalline GaN substrate) having a major surface defined by an m-plane which is a nonpolar plane. A zonal mask 5 extending in a direction intersecting with the plane of FIG. 2 is formed on the substrate 1. The mask 5 is formed by an SiO₂ film, for example. An optical cavity 6 made of a group III nitride semiconductor crystal formed by selective epitaxy growth from the surface of the substrate 1 is arranged on a first side of the mask 5. A reflecting portion 7 is arranged on a second side of the mask 5, to be opposed to the optical cavity 6. The reflecting portion 7 is also made of a group III nitride semiconductor crystal formed by selective epitaxy growth from the surface of the substrate 1.

The optical cavity 6 has a first cavity end face 6A defined by a −c-plane (000-1) on a side of the mask 5 and has a second cavity end face 6B defined by a +c-plane (0001) on a side opposite to the mask 5, while the cavity direction thereof is parallel to a c-axis, and hence parallel to the major surface of the substrate 1. The pair of cavity end faces 6A and 6B are parallel to each other, and perpendicular to the major surface of the substrate 1. A p-electrode 8 is formed on a top face 6C of the optical cavity 6. An n-electrode 9 is formed on a back surface (opposite to the optical cavity 6 etc.) of the substrate 1. The optical cavity 6 has a laser structure including a group III nitride semiconductor multilayer structure formed by a plurality of group III nitride semiconductor layers stacked in a normal direction of the major surface of the substrate 1. FIG. 2 omits illustration of this laser structure, which is described later.

The reflecting portion 7 includes a reflective facet 7A opposed to the first cavity end face 6A through the mask 5, and has a trapezoidal longitudinal section (perpendicular to the major surface of the substrate 1) along the cavity direction. The reflective facet 7A, defined by a (1-101) plane in this embodiment, is a planar surface inclined by an angle of 28° with respect to the major surface of the substrate 1. A reflecting film 10 consisting of a DBR (Distributed Bragg Reflector), for example, is formed on a surface of the reflective facet 7A. This reflecting film 10 is formed over a region reaching a top face 7B of the reflective facet 7A from a portion around an end portion of the reflective facet 7A closer to the substrate 1. The reflecting film 10 formed on the reflective facet 7A forms a reflecting surface 10A opposed to the cavity end face 6A and inclined by the angle of 28° with respect to the major surface of the substrate 1. Therefore, the laser beam 3 outgoing from the cavity end face 6A in the c-axis direction is bent by 124° on the reflecting surface 10A, and progresses in a direction (for separating from the major surface of the substrate 1) intersecting with the major surface of the substrate 1. In other words, the laser beam 3 progresses in a direction inclined by an angle of 124° with respect to the major surface of the substrate 1.

According to this structure, laser oscillation can be caused in the optical cavity 6 by supplying power between the p-electrode 8 and the n-electrode 9. Thus, the laser beam 3 outgoes from the cavity end face 6A along the c-axis direction, to enter the reflecting film 10.

FIG. 3 is a schematic perspective view for illustrating a structural example of the optical cavity 6 in detail. The optical cavity 6 is a Fabry-Perot type resonator constituted of the substrate 1 and a group III nitride semiconductor multilayer structure 11 (group III nitride semiconductor layers) formed on the substrate 1 by crystal growth.

The group III nitride semiconductor multilayer structure 11 includes a light emitting layer 20, an n-type semiconductor layered portion 21 and a p-type semiconductor layered portion 22. The n-type semiconductor layered portion 21 is disposed on a side of the light emitting layer 20 closer to the substrate 1, while the p-type semiconductor layered portion 22 is disposed on a side of the light emitting layer 20 closer to the p-electrode 8. Thus, the light emitting layer 20 is held between the n-type semiconductor layered portion 21 and the p-type semiconductor layered portion 22, whereby a double hetero junction structure is provided. Electrons are injected into the light emitting layer 20 from the n-type semiconductor layered portion 21, while positive holes are injected thereinto from the p-type semiconductor layered portion 22. The electrons and the positive holes are recombined in the light emitting layer 20 to emit light.

The n-type semiconductor layered portion 21 is formed by successively stacking an n-type GaN contact layer 23 (having a thickness of 2 μm, for example), an n-type AlGaN cladding layer 24 (having a thickness of not more than 1.5 μm such as a thickness of 1.0 μm, for example) and an n-type GaN guide layer 25 (having a thickness of 0.1 μm, for example) from the side closer to the substrate 1. On the other hand, the p-type semiconductor layered portion 22 is formed by successively stacking a p-type AlGaN electron blocking layer 26 (having a thickness of 20 nm, for example), a p-type GaN guide layer 27 (having a thickness of 0.1 μm, for example), a p-type AlGaN cladding layer 28 (having a thickness of not more than 1.5 μm such as a thickness of 0.4 μm, for example) and a p-type GaN contact layer 29 (having a thickness of 0.3 μm, for example) on the light emitting layer 20.

The n-type GaN contact layer 23 is a low-resistance layer. The p-type GaN contact layer 29 is a low-resistance layer for attaining ohmic contact with the p-electrode 8. The n-type GaN contact layer 23 is made of an n-type semiconductor prepared by doping GaN with Si, for example, serving as an n-type dopant in a high doping concentration (3×10¹⁸ cm⁻³, for example). The p-type GaN contact layer 29 is made of a p-type semiconductor prepared by doping GaN with Mg serving as a p-type dopant in a high doping concentration (3×10¹⁹ cm⁻³, for example).

The n-type AlGaN cladding layer 24 and the p-type AlGaN cladding layer 28 provide a light confining effect confining the light emitted by the light emitting layer 20 therebetween. The n-type AlGaN cladding layer 24 is made of an n-type semiconductor prepared by doping AlGaN with Si, for example, serving as an n-type dopant (in a doping concentration of 1×10¹⁸ cm⁻³, for example). The p-type AlGaN cladding layer 28 is made of a p-type semiconductor prepared by doping AlGaN with Mg serving as a p-type dopant (in a doping concentration of 1×10¹⁹ cm⁻³, for example).

The n-type GaN guide layer 25 and the p-type GaN guide layer 27 are semiconductor layers providing a carrier confining effect for confining carriers (electrons and positive holes) in the light emitting layer 20. Thus, the efficiency of recombination of the electrons and the positive holes is improved in the light emitting layer 20. The n-type GaN guide layer 25 is made of an n-type semiconductor prepared by doping GaN with Si, for example, serving as an n-type dopant (in a doping concentration of 1×10¹⁸ cm⁻³, for example), while the p-type GaN guide layer 27 is made of a p-type semiconductor prepared by doping GaN with Mg, for example, serving as a p-type dopant (in a doping concentration of 5×10¹⁸ cm⁻³, for example).

The p-type AlGaN electron blocking layer 26 is made of a p-type semiconductor prepared by doping AlGaN with Mg, for example, serving as a p-type dopant (in a doping concentration of 5×10¹⁸ cm⁻³, for example), for preventing the electrons from flowing out of the light emitting layer 20 and improving the efficiency of recombination of the electrons and the positive holes.

The light emitting layer 20, having an MQW (multiple-quantum well) structure containing InGaN, for example, is a layer for emitting light by recombination of the electrons and the positive holes and amplifying the emitted light. More specifically, the light emitting layer 20 is formed by alternately repetitively stacking InGaN sublayers (each having a thickness of 3 nm, for example) and GaN sublayers (each having a thickness of 9 nm, for example) by a plurality of cycles. In this case, the In composition ratio of each InGaN layer is set to not less than 5%, so that the InGaN layer has a relatively small band gap and constitutes a quantum well layer. On the other hand, each GaN layer functions as a barrier layer having a relatively large band gap. The InGaN layers and the GaN layers are alternately repetitively stacked by two to seven cycles, for example, to constitute the light emitting layer 20 having the MQW structure.

The emission wavelength is set to 400 nm to 550 nm, for example, by controlling the In composition in the quantum well layers (InGaN layers). Particularly according to this embodiment, the group III nitride semiconductor multilayer structure 11 having the major growth surface of the nonpolar m-plane is not influenced by polarization charges, dissimilarly to a case having a major growth surface defined by a c-plane. Therefore, the light emitting layer 20 can emit light also when the In composition thereof is increased. Further, the light emitting layer 20 also can emit light in a long wave range (green range of not less than 470 nm, for example), in which a nitride semiconductor laser having a major surface defined by a c-plane cannot emit light.

The p-type semiconductor layered portion 22 is partially removed, to form a ridge stripe 30. More specifically, the p-type contact layer 29, the p-type AlGaN cladding layer 28 and the p-type GaN guide layer 27 are partially removed by etching, to form the ridge stripe 30 having a generally trapezoidal cross-section. This ridge stripe 30 is formed along the c-axis direction. Therefore, the cavity direction is parallel to the c-axis direction.

The group III nitride semiconductor multilayer structure 11 has the cavity end faces 6A and 6B (see FIG. 2 too) on both longitudinal ends of the ridge stripe 30. These cavity end faces 6A and 6B are parallel to each other, and both of the end faces 6A and 6B are perpendicular to the c-axis (i.e., c-planes). Thus, the n-type GaN guide layer 25, the light emitting layer 20 and the p-type GaN guide layer 27 constitute the Fabry-Perot resonator. In other words, the light emitted in the light emitting layer 20 reciprocates between the cavity end faces 6A and 6B, and is amplified by induced emission. Part of the amplified light is extracted from the cavity end face 6A as the laser beam 3.

The p-electrode 8 and the n-electrode 9 are made of Al metal, for example, and in ohmic contact with the p-type contact layer 29 and the substrate 1 respectively. Insulating layers 31 covering the exposed surfaces of the n-type GaN guide layer 27 and the p-type AlGaN cladding layer 28 are so provided that the p-electrode 8 is in contact with only the p-type GaN contact layer 29 provided on the top face of the ridge stripe 30. Thus, a current can be concentrated on the ridge stripe 30, thereby enabling efficient laser oscillation. In the optical cavity 6, a portion located immediately under the ridge stripe 30 on which the current is concentrated forms a waveguide 35 (light guide) for transmitting the light.

According to this structure, light having a wavelength of 400 nm to 550 nm can be emitted by connecting the n-electrode 9 and the p-electrode 8 to a power source and injecting the electrons and the positive holes into the light emitting layer 20 from the n-type semiconductor layered portion 21 and the p-type semiconductor layered portion 22 respectively thereby recombining the electrons and the positive holes in the light emitting layer 20. This light reciprocates between the cavity end faces 6A and 6B along the guide layers 25 and 27, and is amplified by induced emission. Thus, a laser output is extracted mainly from the cavity end face 6A.

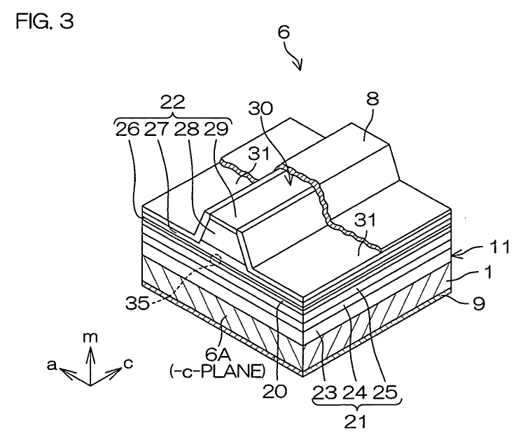

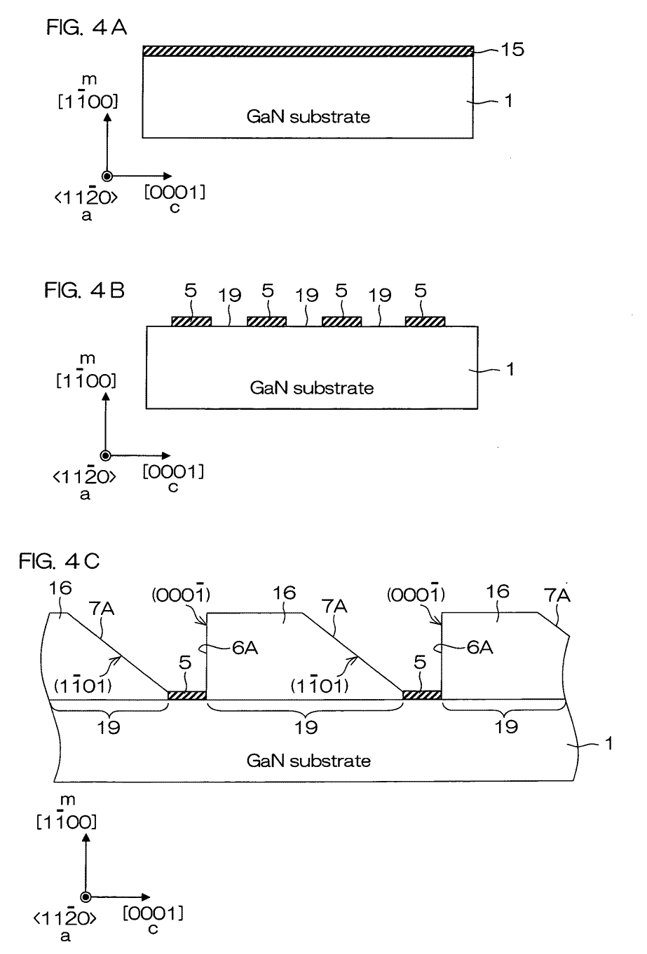

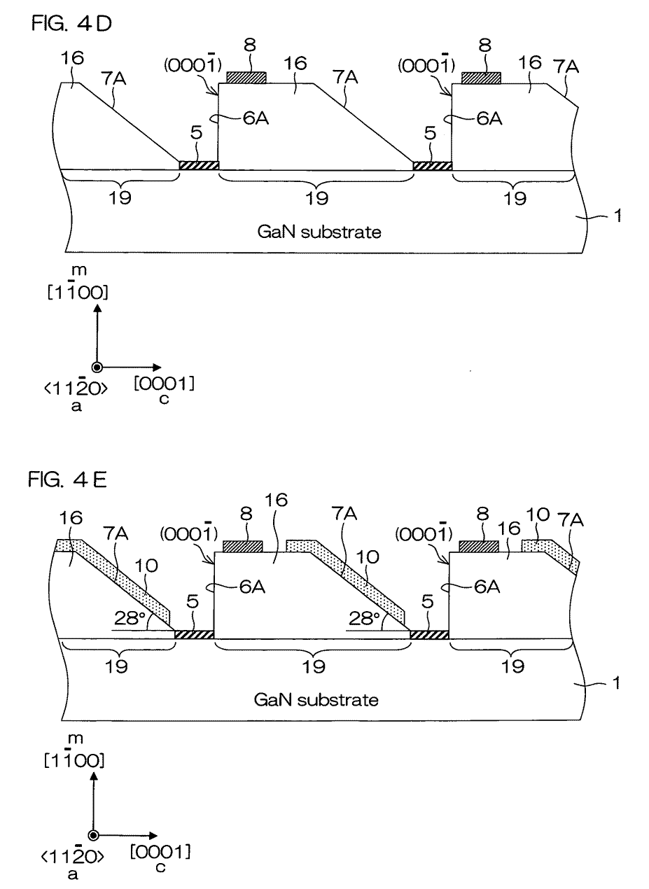

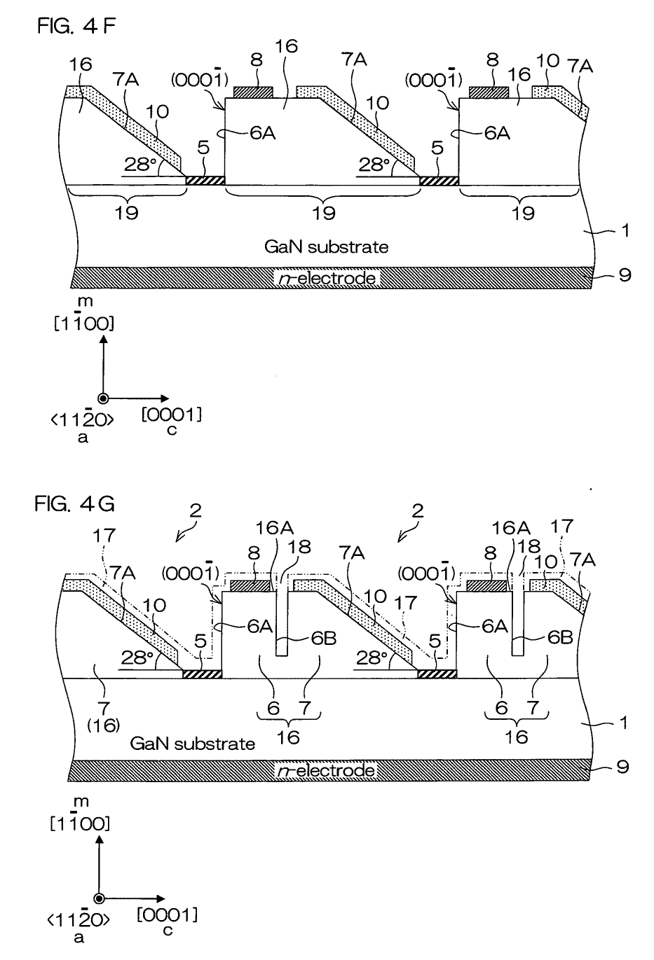

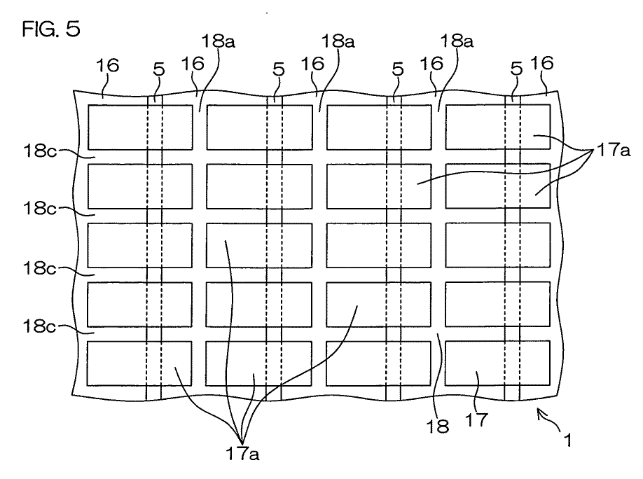

FIGS. 4A to 4G are schematic sectional views successively showing the steps of manufacturing the semiconductor light emitting device. First, an SiO₂ film 15 as a material film for the mask 5 is formed on one major surface of the substrate 1 consisting of the GaN monocrystalline substrate having the major surface defined by the m-plane, as shown in FIG. 4A. The SiO₂ film 15 may be formed by SOG (spin on glass), for example.

Then, the SiO₂ film 15 is patterned in a striped manner by photolithography, whereby a plurality of zonal masks 5 are formed in the striped manner, as shown in FIG. 4B. In other words, each of the masks 5 is formed in a zonal pattern extending along the c-plane (i.e., parallel to the a-axis direction). The regions between the adjacent masks 5 form zonal openings 19 exposing the major surface of the substrate 1.

Then, crystals 16 (inter-mask group III nitride semiconductor crystals) each constituting the group III nitride semiconductor multilayer structure 11 are grown by selective epitaxy through the masks 5 employed as masks for selective growth, as shown in FIG. 4C. In order to grow each crystal 16, GaN (n-type GaN contact layer 23) having a thickness of about 1 μm is grown from the opening 19 between each pair of adjacent masks 5 formed on the GaN substrate 1, for example. Thereafter, the n-type AlGaN cladding layer 24, the n-type GaN guide layer 25, the light emitting layer 20, the p-type AlGaN electron blocking layer 26, the p-type GaN guide layer 27, the p-type AlGaN cladding layer 28 and the p-type GaN contact layer 29 are successively grown.

The crystals 16 are grown on the regions of the zonal openings 19 between the adjacent masks 5. Consequently, the plurality of crystals 16 are formed in a striped pattern extending in the same direction as the masks 5. Each crystal 16 has a long shape extending along c-planes, i.e., along the a-axis direction. The −c-axis side surface of each crystal 16 is defined by the −c-plane (000-1) perpendicular to the major surface of the substrate 1, and employed as the cavity end face 6A. On the other hand, the +c-axis side surface of each crystal 16 is defined by the (1-101) plane inclined at the angle of 28° with respect to the major surface of the substrate 1, and employed as the reflective facet 7A. Referring to each pair of crystals 16 formed on both sides of each mask 5, the crystal 16 on the +c-axis side with respect to the mask 5 provides the cavity end face 6A defined by the −c-plane on the side of the mask 5. On the other hand, the crystal 16 on the −c-axis side with respect to the mask 5 provides the reflective facet 7A defined by the (1-101) plane on the side of the mask 5. Thus, the cavity end face 6A and the reflective facet 7A are opposed to each other through the mask 5.

Then, the ridge stripe 30 (see FIG. 3) is formed on the region of each crystal 16 corresponding to the optical cavity 6, followed by formation of the p-electrode 8, as shown in FIG. 4D. The ridge stripe 30 is formed by dry etching, for example.

Then, the reflecting film 10 is formed on the reflective facet 7A by photolithography, as shown in FIG. 4E.

Then, the n-electrode 9 is formed on the overall region of the back surface (opposite to the optical cavity 6 and the reflecting portion 7) of the substrate 1, as shown in FIG. 4F.

Then, etching for partitioning the crystals 16 is performed, as shown in FIG. 4G. More specifically, an etching mask 17 (shown by two-dot chain lines in FIG. 4G) of a pattern having a plurality of rectangular mask portions 17a corresponding to the laser units 2 respectively is formed as shown in FIG. 5. The rectangular mask portions 17a of the etching mask 17 are arranged in the form of a matrix corresponding to the arrangement of the laser units 2, with lattice openings 18 formed therebetween. The lattice openings 18 are formed by superposing a plurality of a-axial linear openings 18a parallel to one another and a plurality of c-axial linear openings 18c parallel to one another. Each a-axial linear opening 18a is formed on a top face 16A of each crystal 16 along the longitudinal direction (a-axis direction) of this crystal 16. Each c-axial linear opening 18c is formed over a plurality of crystals 16 along the direction (c-axis direction) orthogonal to the longitudinal direction of the crystals 16.

The crystals 16 are divided into the plurality of laser units 2 by dry etching through the etching mask 17. More specifically, each crystal 16 is etched along the corresponding a-axial linear opening 18a, to be divided into a first portion forming the optical cavity 6 and a second portion forming the reflecting portion 7. Thus, the cavity end face 6B of the optical cavity 6 is formed. On the other hand, each crystal 16 is etched along the corresponding c-axial linear opening 18c, to be divided into a plurality of portions arranged along the a-axis direction. This etching may be performed up to a depth exceeding the light emitting layer 20 (see FIG. 3), and is preferably performed up to a depth reaching the n-type GaN contact layer 23.

Films (not shown) for adjusting the reflectivity are formed on the end faces 6A and 6B of the optical cavity 6 constituting each laser unit 2 by magnetron sputtering, for example.

Thus, the pair of the optical cavity 6 and the reflecting portion 7 constituting each laser unit 2 are obtained correspondingly to each rectangular mask portion 17a.

Consequently, the plurality of laser units 2 are arrayed on the substrate 1.

According to the embodiment as hereinabove described, crystal growth for the optical cavity 6 and the reflecting portion 7 can be simultaneously performed by selective epitaxy growth on the substrate 1 having the major surface defined by the m-plane. The first cavity end face 6A of the optical cavity 6 and the reflective facet 7A of the reflecting portion 7 are simultaneously formed in this crystal growth. Therefore, no subsequent crystal regrowth is required for forming the cavity end face and the reflecting surface, whereby the manufacturing steps can be simplified. Further, the cavity end face 6A is formed through the crystal growth for forming the laser structure, whereby the length of the optical cavity 6 in the c-axis direction defines the cavity length L (see FIG. 2) as such. In other words, the emitted light can be amplified by induced emission on the overall region between the cavity end faces 6A and 6B, whereby a high gain can be obtained. The optical cavity 6 is the horizontal cavity having the cavity direction parallel to the major surface of the substrate 1, and hence the cavity length L (400 μm to 600 μm, for example) can be easily controlled, as a matter of course.

The optical cavity 6 formed by the group III nitride semiconductor crystal having the major growth surface of the m-plane is not influenced by polarization charges, dissimilarly to a case having a major growth surface defined by a c-plane. Therefore, the In compositions in the light emitting layer 20 and the guide layers 25 and 27 can be increased with no influence by polarization charges, and the light confinement efficiency can be improved by increasing the thicknesses of the guide layers 25 and 27. If the major crystal growth surface is defined by the c-plane which is a polar plane, carriers are separated due to spontaneous piezoelectric polarization in a quantum well layer (containing In), to deteriorate luminous efficiency. Particularly when the wavelength (in the green wave range, for example) is increased by increasing the In composition, the quantum well layer remarkably causes spontaneous piezoelectric polarization. While the total thickness of the p-type guide layer 25 and the n-type guide layer 27 is about 1000 Å, for example, a built-in voltage is increased due to influence by polarization if the major crystal growth surface is defined by a c-plane. According to this embodiment, however, the laser structure is formed by the group III nitride semiconductor crystal having the major growth surface of the m-plane, whereby separation of carriers resulting from spontaneous piezoelectric polarization can be suppressed, and the luminous efficiency can be improved. Consequently, a threshold voltage necessary for causing laser oscillation can be suppressed, and slope efficiency can be improved. Further, current dependency of the emission wavelength is suppressed due to the suppression of separation of the carriers resulting from spontaneous piezoelectric polarization, whereby a stable oscillation wavelength can be implemented. In addition, the wavelength can be increased by increasing the In composition, and a surface emitting laser source emitting light in the green emission range (with a wavelength of not less than 470 nm and an In composition of not less than 16%) can be provided.

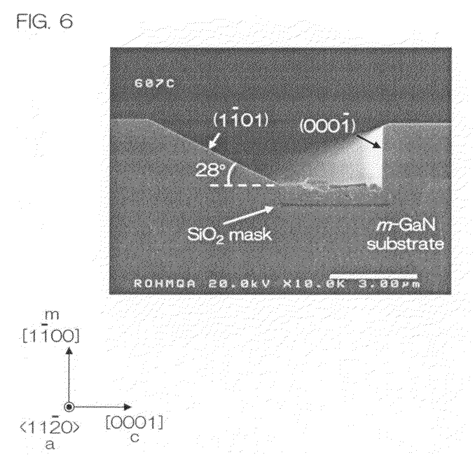

FIG. 6 is a sectional electron micrograph showing a result of an experiment of forming a zonal mask made of SiO₂ on a monocrystalline GaN substrate having a major surface defined by an m-plane and growing GaN crystals on both sides of the zonal mask. It is understood from FIG. 6 that a −c-plane is formed on the +c-axis side of the zonal mask and a (1-101) plane is formed on the −c-axis side of the zonal mask.

When a group III nitride semiconductor is epitaxially grown on a monocrystalline GaN substrate having a major surface defined by an m-plane, a group III nitride semiconductor crystal generally having no dislocation is obtained. Therefore, a device having excellent characteristics can be formed.

While the embodiment of the present invention has been described, the present invention can be carried out also in other modes. For example, while the plurality of laser units 2 are arrayed on the substrate 1 in the aforementioned embodiment, the laser units 2 can also be employed as individual devices, as a matter of course. In this case, the crystals 16 may be divided by cleavage along with the substrate 1. Thus, excellent cavity end faces 6B formed by cleavage can be obtained.

While the substrate 1 having the major surface of the m-plane is employed in the aforementioned embodiment, a similar semiconductor light emitting device can be prepared by employing a substrate (GaN substrate, for example) having a major surface defined by an a-plane, which is another example of the nonpolar plane. When the major surface of the substrate is defined by the m-plane, a −c-axis side facet (reflective facet) of a crystal grown from a mask opening is (1-101). When the major surface of the substrate is defined by the a-plane, on the other hand, a −c-axis side facet (reflective facet) of a crystal grown from a mask opening is (11-22).

While the reflecting film 10 consisting of a DBR is formed on the reflective facet 7A to increase the reflection efficiency in the aforementioned embodiment, the reflecting film 10 may alternatively be formed by a metal film (Al film, for example) having high reflectivity. Further, the reflecting film 10 may be so omitted as to reflect the laser beam 3 by the reflective facet 7A.

While the present invention has been described in detail by way of the embodiments thereof, it should be understood that these embodiments are merely illustrative of the technical principles of the present invention but not limitative of the invention. The spirit and scope of the present invention are to be limited only by the appended claims.

This application corresponds to Japanese Patent Application No. 2007-233015 filed in the Japanese Patent Office on Sep. 7, 2007, the disclosure of which is incorporated herein by reference in its entirety.

What is claimed is:

1. A semiconductor light emitting device, comprising:
an optical cavity made of a group III nitride semiconductor having a major growth surface defined by a nonpolar plane, the optical cavity having a pair of cavity end faces parallel to a c-plane; and
a reflecting portion made of a group III nitride semiconductor having a major growth surface defined by a nonpolar plane, the reflecting portion having a reflective facet opposed to one of the pair of cavity end faces and inclined with respect to a normal of the major growth surface.

2. The semiconductor light emitting device according to claim 1, further comprising a substrate, wherein
the optical cavity and the reflecting portion are made of group III nitride semiconductors crystal-grown from a major surface of the substrate.

3. The semiconductor light emitting device according to claim 2, wherein
the substrate is a group III nitride semiconductor substrate having a major surface defined by a nonpolar plane.

4. The semiconductor light emitting device according to claim 2, wherein
the optical cavity and the reflecting portion are formed by selective epitaxy growth on the major surface of the substrate.

5. The semiconductor light emitting device according to claim 1, further comprising a reflecting film formed on the reflective facet.

6. The semiconductor light emitting device according to claim 1, wherein
a plurality of light emitting units including pairs of the optical cavities and the reflecting portions are arrayed on a substrate.

7. A method of manufacturing a semiconductor light emitting device including an optical cavity and a reflecting portion formed on a substrate, the optical cavity having a cavity direction parallel to a major surface of the substrate, the reflecting portion being arranged to reflect a laser beam generated by the optical cavity in a direction not parallel to the major surface of the substrate, the method comprising:
a mask forming step of forming a mask of a prescribed pattern having openings corresponding to regions for forming the optical cavity and the reflecting portion on the substrate; and
a crystal growth step of simultaneously forming a first group III nitride semiconductor crystal having a facet parallel to a c-plane defining a first cavity end face of the optical cavity and a second group III nitride semiconductor crystal for the reflecting portion having a reflective facet opposed to the first cavity end face and inclined with respect to a normal of the major surface of the substrate by growing a group III nitride semiconductor having a major surface defined by a nonpolar plane by selective epitaxy growth from the major surface of the substrate exposed from the openings of the mask.

8. The method of manufacturing a semiconductor light emitting device according to claim 7, further comprising a step of forming a second cavity end face of the optical cavity by partitioning the first group III nitride semiconductor crystal on a position separating by a prescribed cavity length from the first cavity end face of the optical cavity.

9. The method of manufacturing a semiconductor light emitting device according to claim 7, wherein
the mask forming step includes a step of forming a plurality of linear masks on the major surface of the substrate in a striped manner,
the crystal growth step includes a step of growing an inter-mask group III nitride semiconductor crystal having a facet parallel to a c-plane on a side of a first linear mask and having another facet inclined with respect to the normal of the major surface of the substrate on a side of a second linear mask between each pair of linear masks adjacent to each other thereby opposing the facet forming the first cavity end face of the optical cavity and the reflective facet of the reflecting portion to each other in between each linear mask, and
the method further comprises a step of forming a second cavity end face of the optical cavity by partitioning the inter-mask group III nitride semiconductor crystal between each pair of linear masks adjacent to each other on a position separating by a prescribed cavity length from the first cavity end face.

10. The method of manufacturing a semiconductor light emitting device according to claim 9, further comprising a step of partitioning the inter-mask group III nitride semiconductor crystal at an interval along the linear masks.

11. The method of manufacturing a semiconductor light emitting device according to claim 7, further comprising a step of forming a reflecting film on the facet of the reflecting portion.
